(19) United States
(12) Patent Application Publication
(10) Pub. No.: US 2021/0126570 A1
(43) Pub. Date: Apr. 29, 2021

(54) ELECTRIC DRIVER CONTROL SYSTEM AND METHOD THEREOF

(71) Applicant: Janardhana Swamy, Bangalore (IN)

(72) Inventor: Janardhana Swamy, Bangalore (IN)

(21) Appl. No.: 16/604,634

(22) PCT Filed: Apr. 13, 2018
(86) PCT No.: PCT/IN2018/050210

§ 371 Date: Oct. 11, 2019

(30) Foreign Application Priority Data
Apr. 13, 2017 (IN) 201741013364

(51) Int. Cl. H02P 29/024; G01R 31/34; F04D 13/06

(52) U.S. Cl. CPC H02P 29/024; F04D 15/0218; F04D 13/06; G01R 31/343

(57) ABSTRACT

The invention provides an electric driver control system and method that utilizes detection of change in current signature of an electric driver to automatically switch on/off and operate the driver. The change in current signature corresponds to a change in the conditions of the system driven by the electric driver.

### TECHNICAL FIELD

This invention generally relates to home and industrial automation and more specifically relates to a system and method for detecting and analyzing changes in the current signature of an electric driver wherein such changes signify a corresponding change in conditions of the system driven by the electric driver.

### BACKGROUND ART

Motor Current Signature Analysis (MCSA) is a well-recognized mechanism used in present day industries to detect faults in motors and other electric drivers. MCSA relies on the broad principle that any deviation from a Normal Current Signature pattern is a direct result of presence of a fault in the electric driver system and different unique current signature patterns correspond to different types of faults. Though MCSA has been thoroughly researched upon and used in the industrial fault detection and maintenance domain, it is yet to find implementation in other fields of life.

Automation is one of the fastest growing industries today and is a major contributor in making everyday lives safer and more convenient. Be it home or industrial automation, the world is attempting to achieve systems that do not require human intervention and are intelligent enough to take decisions. However, most research and development in the automation domain is concentrated towards achieving greater system independence while the ease of installation of such systems is rather neglected. As a result we have systems today that automate an entire activity, but are extremely complex to install and prohibitively expensive.

Lets consider a home automation example of pumping water using a centrifugal pump from a sump to a tank. Generally, water is stored in tanks placed on the top of buildings and a motor is used to replenish water into the tank from an underground water storage (sump). Traditionally, the motor used to be manually switched on by a user when the water level in tank was low and switched off when the tank was full. This has been automated with the help of various automation technologies including sensors immersed within the water tank that communicate the water level to a motor controller through wired or wireless means and based on the level of water the controller automatically operates the motor. Though the problem of manually switching on and off the motor is resolved through this, but it poses a far greater problem of complex installation and prohibitive cost. For the sensors to communicate water level to the motor controller, complex wire installations have to be carried out from the tank at the top of the building to the motor controller that is generally installed at the base of the building, especially in tall buildings where wireless means are not effective. This wiring requires a lot of installation time, man power and expense and affecting the décor of the building. Further, the cost of maintenance also significantly increases, as the sensors have to be frequently replaced due to constant contact with water and requires continuous monitoring and maintenance.

Therefore, there is a great need of a system that not only automates a specific function but also achieves such automation with great ease and simplified installation without requirement of constant monitoring and maintenance. The current invention aims at achieving industrial and home automation, specifically for electric driver driven systems without indulging in complex and expensive installations.

### SUMMARY OF INVENTION

The present invention provides an electric driver control system and the method of controlling the same. The system consists of a power supply source, a controller in electric communication with the power supply source, an electric driver in electric communication with the controller, a driven system connected to the electric driver and a current signature sensor communicatively coupled with the controller and the electric driver. The electric driver is configured to receive power from the power supply source through the controller whereas the driven system is configured to be operated by the electric driver. The current signature sensor is configured to sense change in current signature of the electric driver corresponding to a change in a condition of the driven system and the controller is further configured to carry out a preset action, on the electric driver which in turn operates the driven system, corresponding to the change in current signature.

### BRIEF DESCRIPTION OF DRAWINGS

This invention is illustrated in the accompanying drawings, throughout which, like reference letters indicate corresponding parts in the various figures. The embodiments herein will be better understood from the following description with reference to the drawings, in which:

FIG. 1 depicts/illustrates details of the components of a system configured to detect changes in current signature of an electric driver in accordance with the present invention

FIG. 2 depicts/illustrates details of an illustrative embodiment that shows a system for controlling a motor that pumps water from a sump to a tank, in accordance with the present invention.

FIG. 3 depicts/illustrates in detail the components and working of the controller, in accordance with an embodiment of the invention.

FIG. 4 depicts/illustrates the details of the method of controlling the operation of the electric driver, in accordance with an embodiment of the invention.

### DESCRIPTION OF EMBODIMENTS

The embodiments herein, the various features and advantageous details thereof are explained more fully with reference to the non-limiting embodiments that are illustrated in the accompanying drawings and/or detailed in the following description. Descriptions of well-known components and processing techniques are omitted to not unnecessarily obscure the embodiments herein. The examples used herein are intended merely to facilitate an understanding of ways in which the embodiments herein may be practiced and to further enable those of skilled in the art to practice the embodiments herein. Accordingly, the examples should not be construed as limiting the scope of the embodiments herein.

The invention provides an automation system and method for detecting changes in the current signature of an electric driver based on a change in the condition of the system being driven by the electric driver. A controller is installed between the mains power supply and the electric driver driving the system. The controller is configured to measure the current signature of the electric driver and any variations thereof. The controller may achieve this with the help of various current signature measuring technologies known now or developed in the future. Some of such technologies known today may include Hall Effect sensor, Shunt sensor, current transformer, Rogowski coil, fiber optic current sensor and other specifically developed transducers and sensors (together classified and referred to as “current signature sensors” for the purposes of this draft).

The change in the conditions of the system may be understood as any change that correspondingly brings about a change in the current signature of the electric driver. These conditions may include but not be limited to change in the type of load carried by the system, the speed of a moving system, variation in the amount of material that the system carries/pumps, etc. The change in the current signature is often due to more than one parameter change in the system. Therefore, accurate understanding of other parameters such as voltage, power factor, AC frequency, condition of electric driver etc also plays an important role in understanding the current signature of the electric driver and not just the variation in the amount of material that the system carries/pumps. Once the electric driver is switched on, the controller may sense the standard current utilized by the electric driver. Based on any change in the condition of the driven system, there will be a change in current signature, which is sensed by the controller and the controller is further programmed to carry out certain actions based on detected change in current signature.

In the present context, an electric driver may refer to a machine or a motor that converts electrical energy into mechanical energy. A driven system may be any load that is driven by the electric driver. For example, consider an elevator system in a building, the elevator is considered a driven system and the elevator motor is considered the driver system. According to the present invention, by detecting the current utilized by the elevator motor, the controller estimates the approximate number of people traveling or the weight of the object being lifted and thereby take action accordingly.

Referring now to the drawings, where similar reference characters denote corresponding features consistently throughout the figures, there are shown preferred embodiments.

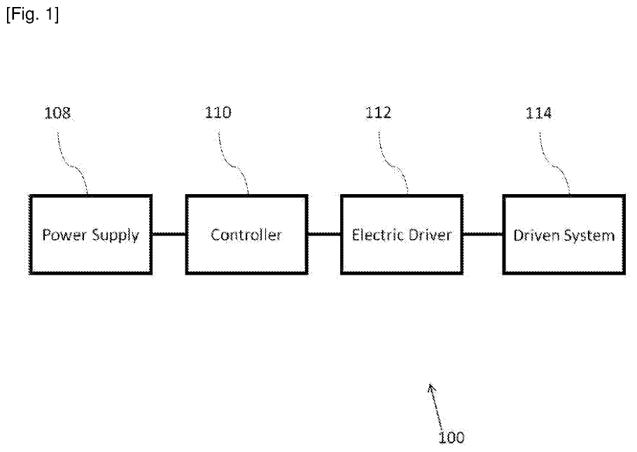

FIG. 1 depicts/illustrates details of an apparatus 100 that explains the working of a system 114 driven by an electric driver 112 for detecting changes in conditions of the driven system 114, in accordance with the present invention. Once the current from the power supply 108 reaches the electric driver 112 through the controller 110, the driven system 114 is accordingly operated by the electric driver 112. The controller 110 detects the current signature of the electric driver 112 when the electric driver is working on the driven system in standard condition. This current signature may be referred to as Normal Current Signature.

Once there is a change in the condition of the driven system 114, there is a corresponding change in the current signature of the electric driver 112 that is detected by the controller 110. The controller 110 is pre configured to either communicate the change in the current signature by means of audio and or visual means or send the detected change related information to a server or device by wired or wireless means or store it in its local memory. Alternatively, the controller 110 may be configured to perform preset actions based on the detected change such as switching off the electric driver, decreasing/increasing the speed of the electric driver, etc.

In one embodiment, the detected change in the current signature is further processed in the controller 110 to change the condition of the driven system 114 by means of controlling the electric driver 112. For example, consider the elevator scenario stated earlier, where by detecting the current utilized by the elevator motor, the controller estimates the approximate number of people traveling in the elevator. This data may be further used to communicate overload condition, stop elevator at a safe level etc.

The controller 110 may be configured to carry out specific actions once it detects the change in current signature. These actions may either be locally taken by the controller or may be based on the instructions communicated by a server or a user device. The instructions may be fed to the controller in multiple ways i.e. firstly, specific actions may be hard coded in the controller 110 and the controller is able to take these actions without any external assistance; secondly, the controller 110 may have a local UI disposed within the controller 110 wherein a user may press preset buttons to carry out specific operations; thirdly the controller 110 may receive instructions through a server or a user device. The server may be further used to set conditions based on which the controller 110 may operate the electric driver. The server may set conditions such as periodic switching on/off of the electric driver, a specific quiet period when the electric driver may not operate, specific time periods and/or specific week days for operating the electric driver, specific speeds of operation, specific actions to be carried out based on current signature without any intervention etc or combinations thereof. The server may also receive instructions from a user device including switching on/off the electric driver at specific time intervals, on specific days, when user device is at a particular geo location, or carry out other actions or change settings in the controller etc or any combinations thereof. In an alternate embodiment, the user device may directly communicate with the controller 110 through wireless protocols known today or developed in the future to switch on/off or operate the electric driver 112.

In an alternate embodiment a specific remote control device may be specially designed for operating the controller 110. This remote control device may utilize known wireless protocols to operate the controller 110. In yet another alternate embodiment, the controller may contain a small screen to visually depict data to the user including different states of the driven system.

In one embodiment, the server may be configured with a continuous learning and predictive module that instructs the controller 110 to operate the electric driver 112 based on the usage patterns of the driven system. In another embodiment the controller itself is configured with the predictive and continuous learning module.

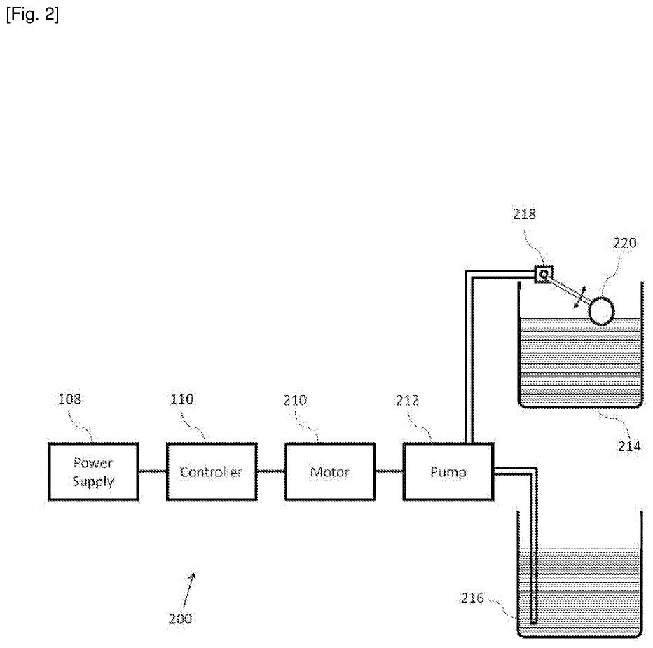

In one illustrative implementation, the described system may be applied to a motor designed to pump liquid or other substances from a source to a destination storage unit. FIG. 2 depicts an illustrative embodiment that shows a system 200 installed in a building for controlling a motor (electric driver) 210 that drives a pump 212 (driven system) for pumping water from a sump 216 to a tank 214, in accordance with the present invention. The system 200 includes power supply 108, a controller 110, a motor 210, a pump 212, a water reservoir or a sump 216 and a float valve 218 disposed within a tank 214.

The float valve 218 opens and closes as the water level moves the float 220 down or up respectively based on the level of the water in the tank 214. In alternate embodiments, any opening and closing mechanism instead of float valve may be used and the same is intended to be covered within the scope of this invention. When the float valve opens it permits the water to be filled into the tank 214 and once the tank 214 is full, the float valve closes thereby cutting off the water supply to the tank 214. Once the current flows from power supply 108 to the motor 210, the motor drives the pump 212 and water is pumped from the sump 216 to the tank 214. The controller 110 detects the Normal Current Signature of the motor 210 when the water is being filled into the tank 214. Once the tank 214 is full, the float 220 moves up closing the float valve 218 and no more water flows into the tank 214 even though the pump 212 is being driven by motor 210. This condition affects the loading condition on the pump and results in current signature change for the motor 210 and this change is detected by the controller 110. The current signature when the tank is full may be referred to as Full Current Signature. When the controller 110 identifies the Full Current Signature, the controller 110 may switch off the motor by disrupting the current flow to the motor with the help of a relay and/or the controller may communicate full tank condition via audio and/or visual means such as light signal, buzzer, alarm etc.

Another possible condition may be when the sump 216 has no more water left and the pump pumps only air or partial water and partial air to the tank 214. This also causes a change in current signature of the motor 210. This current signature when no water is left to pump may be referred to as Dryrun Current Signature. When the controller 110 identifies the Dryrun Current Signature, the controller 110 may communicate the same in different possible ways as described above and/or control the pump.

Further, the system 200 as discussed in FIG. 2 can be extended to any motor that can pump a liquid or fine solid particles from a source to a destination storage unit.

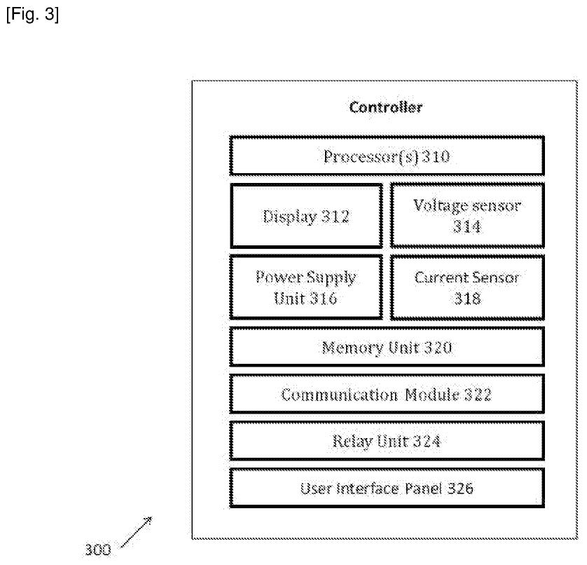

FIG. 3 illustrates the details of the components 300 of the controller, in accordance with an embodiment of the invention. The controller has a processor 310 that is configured to process actions based on detecting changes in Current Signature of any electric driver. In an exemplary embodiment a display 312 may be disposed on the controller to indicate status of the controller and other data. A power supply unit 316 within the controller facilitates power to the controller to carry out its functions. A memory unit 320 may be disposed within the controller to store operating data for future use, hard coded instructions for taking specific actions, acquired/observed data, current signature data and other important data needed for the functioning of the controller. A communication module 322 within the controller ensures wired (usb, Ethernet or any other means now known or developed in the future) or wireless (such as infrared, unitrasonic, wifi, GSM, Bluetooth or any other means now known or developed in the future) communication between the controller and any user device, specially created remote control or server. A relay unit 324 may be controlled by the processor 310 to turn on or turn off electric power supply to the electric driver. A voltage sensor 314 may be configured to sense the voltage levels in the incoming power supply. A current sensor 318 may be disposed within the controller to measure the current being consumed by the electric driver. A user interface panel 326 may be optionally disposed on the controller to help a user locally operate the controller without the use of a device, remote or server or any other wired or wireless means.

In an alternate embodiment overriding buttons/switches may be disposed on the controller that may override all other functionality of the controller and may instruct the controller to act in a specific way. For example there may be an “off overriding switch” that, when pressed, may result in the controller switching off the power supply to the electric driver irrespective of any different user settings supplied by a server, remote or user device. An “on overriding switch” may be used to keep the electric driver switched on until switched off. Yet another overriding switch could be the “on with automatic off overriding switch” which may immediately enable the controller to switch on the power supply to the electric driver when pressed and may enable the controller to automatically switch off the power supply when the current consumption signature changes (e.g. when the tank is full).

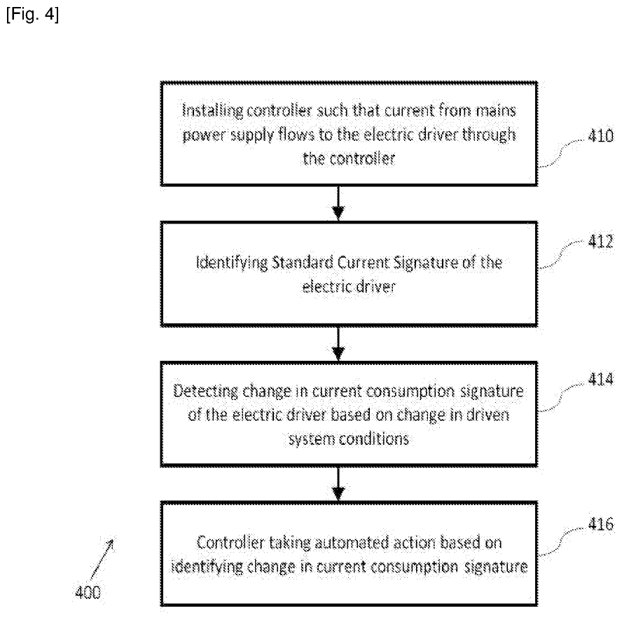

FIG. 4 depicts/illustrates the details of the method 400 of detecting change in current signature of an electric driver and controlling the operation of the driver, in accordance with the present invention. The controller is installed in such a manner that current from the mains power supply flows to the electric driver via the controller 410. The controller identifies the Normal Current Signature of the electric driver 412 and is configured to detect any deviations from this Normal Current Signature. Once there is a change in the conditions of the system driven by the electric driver, the current signature of the electric driver changes and this change is detected by the controller 414. Based on this detection the controller automatically takes actions 416.

The foregoing description of the specific embodiments will so fully reveal the general nature of the embodiments herein that others can, by applying current knowledge, readily modify and/or adapt for various applications such specific embodiments without departing from the generic concept, and, therefore, such adaptations and modifications should and are intended to be comprehended within the meaning and range of equivalents of the disclosed embodiments. It is to be understood that the phraseology or terminology employed herein is for the purpose of description and not of limitation. Therefore, while the embodiments herein have been described in terms of preferred embodiments, those skilled in the art will recognize that the embodiments herein can be practiced with modification within the scope of the embodiments as described herein.

1. An electric driver control system comprising:
a power supply source;
a controller in electric communication with the power supply source;
an electric driver in electric communication with the controller, the electric driver configured to receive power from the power supply source through the controller;
a driven system connected to the electric driver, the driven system configured to be operated by the electric driver;
a current signature sensor communicatively coupled with the controller and the electric driver, the current signature sensor configured to sense change in current signature of the electric driver corresponding to a change in a condition of the driven system; and
the controller further configured to carry out a preset action, on the electric driver which in turn operates the driven system, corresponding to the change in current signature.

2. The system as claimed in claim 1 further comprising a communication module disposed within the controller, the communication module configured to communicate the change in current signature to a server or user device.

3. The system as claimed in claim 2 wherein the communication module is a wireless communication module.

4. The system as claimed in claim 2 wherein the communication module is a wired communication module.

5. The system as claimed in claim 1 further comprising audio means to sound an alert based on specific change in current signature of the electric driver controlling the driven system.

6. The system as claimed in claim 1 further comprising visual means to alert a user based on specific change in current signature of the electric driver controlling the driven system.

7. The system as claimed in claim 1, the controller further configured to receive instructions from a server or a user device to carry out specific operations on the electric driver.

8. The system as claimed in claim 1 further comprising an override switch, the override switch configured to permit overriding of all preset functionality and take a specific action.

9. The system as claimed in claim 1 further comprising a display unit communicatively coupled with the controller, the display unit configured to display system status and data.

10. The system as claimed in claim 1 further comprising a relay unit controlled by the controller, the relay unit configured to control the power supply to the electric driver.

11. The system as claimed in claim 1 further comprising a continuous learning and predictive module that is configured to send instructions to the controller based on usage patterns of the driven system.

12. The system as claimed in claim 1 wherein the electric driver is a motor configured to pump a liquid from a source to a destination storage unit and the driven system is a pump configured to pump liquid from the source to the destination storage unit.

13. A method of controlling an electric driver, said method comprising:
supplying power from a power source to an electric driver through a controller;
the electric driver controlling a driven system based on power supplied;
sensing change in current signature of the electric driver by a current signature sensor corresponding to a change in a condition of the driven system; and
the controller carrying out a preset action, on the electric driver which in turn operates the driven system, corresponding to the change in current signature.

14. The method as claimed in claim 13 further comprising communicating change in current signature to a server or user device through a communication module.

15. The method as claimed in claim 13 further comprising the controller receiving instructions from a server or a user device to carry out specific operations on the electric driver.
